(19) United States
(12) Patent Application Publication
(10) Pub. No.: US 2021/0079526 A1
(43) Pub. Date: Mar. 18, 2021

(54) SUBSTRATE PROCESSING APPARATUS AND SHOWER HEAD

(71) Applicant: Tokyo Electron Limited, Tokyo (JP)

(72) Inventor: Hachishiro IIZUKA, Yamanashi (JP)

(73) Assignee: Tokyo Electron Limited, Tokyo (JP)

(21) Appl. No.: 16/953,363

(22) Filed: Nov. 20, 2020

Related U.S. Application Data
(63) Continuation of application No. PCT/JP2019/020892, filed on May 27, 2019.

(30) Foreign Application Priority Data
Jun. 7, 2018 (JP) 2018-109760

(51) Int. Cl. C23C 16/455; C23C 16/505

(52) U.S. Cl. CPC C23C 16/45565; C23C 16/505

(57) ABSTRACT

A substrate processing apparatus includes a chamber, a placing pedestal, and a shower head. The shower head includes a first base member, a second base member, a shower plate, and a plurality of heat transfer members. The first base member includes a first cylindrical wall, a second cylindrical wall, and a first upper wall. The second base member includes a third cylindrical wall, a fourth cylindrical wall, and a second upper wall. The shower plate includes a plurality of through holes and is fixed to a lower end of the second cylindrical wall and a lower end of the fourth cylindrical wall. Each of the heat transfer members is arranged between the first upper wall and the second upper wall, and is in contact with a lower surface of the first upper wall and an upper surface of the second upper wall.

### CROSS-REFERENCE TO RELATED APPLICATIONS

The present application is a continuation of PCT International Application No. PCT/JP2019/020892 filed on May 27, 2019 which claims the benefit of priority from Japanese Patent Application No. 2018-109760 filed on Jun. 7, 2018, the entire contents of which are incorporated herein by reference.

### FIELD

Exemplary embodiments disclosed herein relate to a substrate processing apparatus and a shower head.

### BACKGROUND

In a semiconductor device manufacturing process, a process such as a film forming process is performed on a substrate such as a semiconductor wafer. As a film forming method, for example, there is an atomic layer deposition (ALD) method or the like. While heating a substrate that is an object of film forming, a film forming apparatus that performs film forming by the ALD method repeats a cycle of supplying a precursor into a reaction chamber and performing a purge on a substrate. Thus, atomic layers are deposited one by one on a surface of the substrate and a desired film is formed on the substrate in such a film forming apparatus, a placing pedestal on which the substrate is placed and a gas supply unit that supplies processing gas to the substrate placed on the placing pedestal face each other in a processing container, and the processing gas is supplied in a form of a shower from the gas supply unit (see, for example, US Patent Application Publication No. 2009/0218317).

The above-described gas supply unit is called a shower head or the like, and has a processing gas introduction port and a gas supply hole formed in a lowermost part. Also, the shower head has a diffusion space to horizontally diffuse the gas between the introduction port and the gas supply hole.

In the shower head of US Patent Application Publication No. 2009/0218317, a diffusion space is divided into three, diffusion spaces adjacent to each other are separated by a partition wall, and a gas supply hole is provided in each of the diffusion spaces. This shower head can control a supply amount of processing gas with respect to a substrate and form a film with a uniform thickness by individually adjusting a supply amount of the processing gas supplied to each diffusion space.

Note that in the shower head of US Patent Application Publication No. 2009/0218317, a central diffusion space is formed in a disk shape in a plan view, an outermost diffusion space is formed in an annular shape in the plan view, and an intermediate diffusion space placed between the two diffusion spaces is also formed in an annular shape in the plan view. Also, in this shower head, a plurality of processing gas introduction ports each of which has a circular shape in the plan view is formed at positions overlapping with the diffusion spaces, each of which has the annular shape in the plan view, in the plan view.

Incidentally, in a diffusion space provided in a shower head, a member located above and a member located below are separated with the diffusion space interposed therebetween. Although there is some heat transfer between the member located above and the member located below via processing gas flowing in the diffusion space, a heat transfer coefficient of the processing gas flowing in the diffusion space is lower than a heat transfer coefficient of a partition wall defining the diffusion space. Thus, even when a temperature distribution of the member located above the diffusion space is controlled, it is difficult to cause a temperature distribution of the member located below the diffusion space to be a desired distribution.

### SUMMARY

According to an aspect of a present disclosure, a substrate processing apparatus includes a chamber a placing pedestal and a shower head. The placing pedestal is arranged in the chamber. A substrate to be processed is placed on the placing pedestal. The shower head is arranged at a position facing the placing pedestal and supplies gas into the chamber. The shower head includes a first base member, a second base member, a shower plate, and a plurality of heat transfer members. The first base member includes a first cylindrical wall, a second cylindrical wall, and a first upper wall. The first cylindrical wall has a cylindrical shape. The second cylindrical wall has a cylindrical shape coaxial with the first cylindrical wall, and has a larger diameter than the first cylindrical wall. The first upper wall connects a lower end of the first cylindrical wall and an upper end of the second cylindrical wall. The second base member includes a third cylindrical wall, a fourth cylindrical wall, and a second upper wall. The third cylindrical wall has a cylindrical shape coaxial with the first cylindrical wall, has a smaller diameter than the first cylindrical wall, and is arranged in a space surrounded by the first cylindrical wall. The fourth cylindrical wall has a cylindrical shape coaxial with the first cylindrical wall, has a larger diameter than the third cylindrical wall, has a smaller diameter than the second cylindrical wall, and is arranged in a space surrounded by the second cylindrical wall. The second upper wall is arranged below the first upper wall, and connects a lower end of the third cylindrical wall and an upper end of the fourth cylindrical wall. The shower plate includes a plurality of through holes, and is arranged at a lower end of the second cylindrical wall and a lower end of the fourth cylindrical wall. Each of the heat transfer members is arranged between the first upper wall and the second upper wall and is in contact with a lower surface of the first upper wall and an upper surface of the second upper wall.

### BRIEF DESCRIPTION OF DRAWINGS

FIG. 1 is a schematic cross-sectional view illustrating an example of a plasma processing apparatus in a first exemplary embodiment of the present disclosure;

FIG. 2 is an enlarged cross-sectional view illustrating an example of a shower head in the first exemplary embodiment;

FIG. 3 is a cross-sectional view illustrating one example of a first base member;

FIG. 4 is a top view illustrating the one example of the first base member;

FIG. 5 is a bottom view illustrating the one example of the first base member;

FIG. 6 is a cross-sectional view illustrating one example of a second base member;

FIG. 7 is a top view illustrating the one example of the second base member;

FIG. 8 is a bottom view illustrating the one example of the second base member;

FIG. 9 is a cross-sectional view illustrating one example of a third base member;

FIG. 10 is a top view illustrating the one example of the third base member;

FIG. 11 is a bottom view illustrating the one example of the third base member;

FIG. 12 is a schematic cross-sectional view illustrating an example of a plasma processing apparatus in a second exemplary embodiment of the present disclosure;

FIG. 13 is an enlarged cross-sectional view illustrating an example of a shower head in the second exemplary embodiment;

FIG. 14 is an enlarged cross-sectional view illustrating an example of a shower head in a third exemplary embodiment;

FIG. 15 is a view illustrating an example of a position of a placing pedestal in execution of a process; and

FIG. 16 is a view illustrating an example of a position of the placing pedestal in execution of cleaning.

### DESCRIPTION OF EMBODIMENTS

Exemplary embodiments of a substrate processing apparatus and shower head disclosed in the present application will be explained below in detail with reference to the accompanying drawings. Note that the disclosed substrate processing apparatus and shower head are not limited to the exemplary embodiments explained below.

### First Exemplary Embodiment

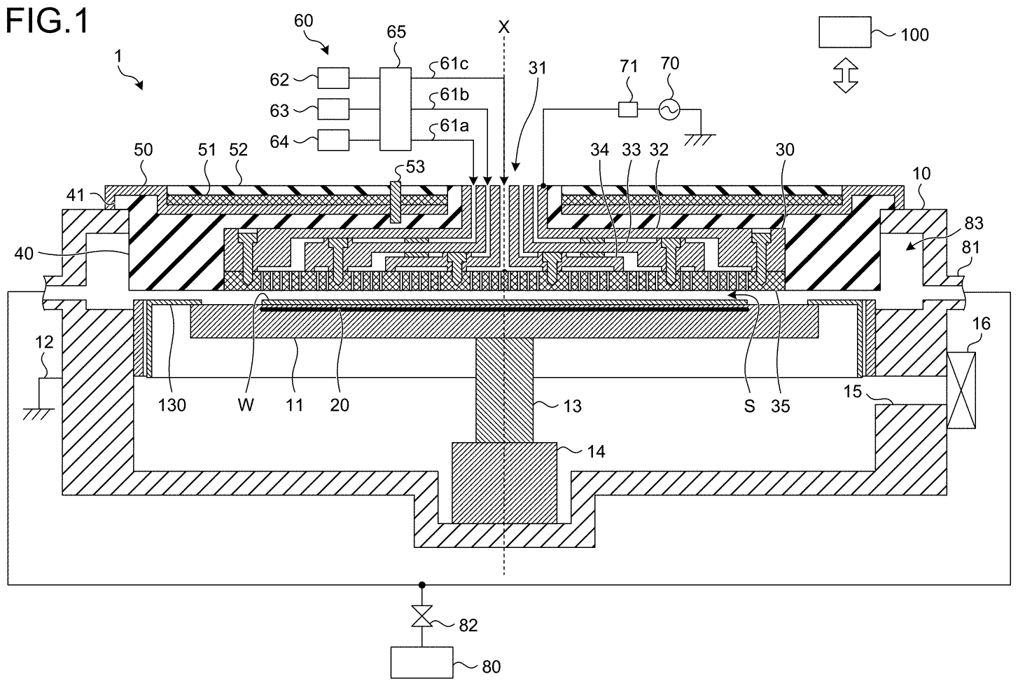

Structure of plasma processing apparatus 1 FIG. 1 is a schematic cross-sectional view illustrating an example of the plasma processing apparatus 1 in the first exemplary embodiment of the present disclosure. The plasma processing apparatus 1 in the present exemplary embodiment is a capacitively coupled plasma (CCP) processing apparatus. The plasma processing apparatus 1 is an example of a substrate processing apparatus. The plasma processing apparatus 1 in the present exemplary embodiment performs a film forming process of a SiO₂ film by the AID method on a semiconductor wafer N (hereinafter, described as wafer W) that is an example of a substrate to be processed. More specifically, the plasma processing apparatus i forms a SiO₂ film on the wafer W by plasma enhanced ALD (PEALD).

The plasma processing apparatus 1 includes a substantially cylindrical chamber 10 which has a bottom and an upper side of which is opened. The chamber 10 is formed, for example, of a metal material such as aluminum or nickel and is grounded by a grounding wire 12. An inner wall of the chamber 10 is covered, for example, with a liner (not illustrated) on a surface of which a spray-coated film made of a plasma resistant material is formed. In the chamber 10, a placing pedestal 11 on which the wafer W is placed is provided.

The placing pedestal 11 is formed, for example, of a metal material such as aluminum or nickel. A lower surface of the placing pedestal 11 is supported by a support member 13 formed of a conductive material. The support member 13 can be lifted/lowered by a lifting/lowering mechanism 14. The lifting/lowering mechanism 14 can lift/lower the placing pedestal 11 by lifting/lowering the support member 13.

A periphery of the placing pedestal 11 is covered with a cover member 130 made of an insulating or dielectric material. The placing pedestal 11 is electrically grounded to the chamber 10 via the support member 13 and the lifting/lowering mechanism 14. The placing pedestal 11 functions as a lower electrode paired with a shower head 30 (described later) that functions as an upper electrode. Note that a configuration of a lower electrode is not limited to contents of the present exemplary embodiment, and may be, for example, a configuration of an insulating or dielectric member in which a conductive member such as metal mesh is embedded in a placing pedestal 11.

A heater 20 is built in the placing pedestal 11, and can heat the wafer W placed on the placing pedestal 11 to a predetermined temperature. Also, the placing pedestal 11, an electrode (not illustrated) is embedded inside an insulating or dielectric layer arranged on an upper surface thereof. Electrostatic force generated on the placing pedestal 11 by a DC voltage supplied to the electrode causes the wafer W placed on the placing pedestal 11 to be attracted to and held on the upper surface of the placing pedestal 11.

An opening 15 for carry-in and carry-out of the wafer N is formed in a side wall of the, chamber 10. The opening 15 can be opened/closed by a gate valve 16. A plurality of support pins (not illustrated) is provided below the placing pedestal 11 and inside the chamber 10, and insertion holes (riot illustrated) for insertion of the support pins are formed in the placing pedestal 11. Thus, when the placing pedestal 11 is lowered to a carry-in/carry-out position of the wafer W, the wafer W is received by upper end parts of the support pins that penetrate the insertion holes in the placing pedestal 11, and the wafer P can be delivered to/from a transfer arm (not illustrated) that enters from the opening 15 of the chamber 10.

A shower head 30 is provided above the placing pedestal 11 and inside the chamber 10. The shower head 30 is arranged in such a manner as to be substantially parallel to the placing pedestal 11. In other words, the shower head 30 is arranged in such a manner as to face the wafer W placed on the placing pedestal 11. In a space inside the chamber 10, a space between the wafer W placed on the placing pedestal 11 and the shower head 30 is specifically described as a processing space S. The shower head 30 is formed of a conductive metal such as aluminum or nickel.

The shower head 30 is supported by an insulating member 40 formed of a dielectric material such as quartz. The insulating member 40 is supported on an upper part of the chamber 10 by a locking unit 41 that projects outward from the insulating member 40. As a result, the shower head 30 is supported by the chamber 10 via the insulating member 40.

The shower head 30 includes a first base member 32, a second base member 33, a third base member 34, and a shower plate 35. Each of the first base member 32, the second base member 33, and the third base member 34 is circular in plan view, and is arranged in such a manner that a center thereof becomes an axis X. The shower plate 35 is provided at lower ends of the first base member 32, the second base member 33, and the third base member 34. A plurality of through holes is provided in the shower plate 35. Between the first base member 32 and the second base member 33, between the second base member 33 and the third base member 34, and inside the third base member 34, processing gas is supplied from a gas supply mechanism 60 through a gas introduction unit 31 of the shower head 30. The processing gas supplied between the first base member 32 and the second base member 33, between the second base member 33 and the third base member 34, and inside the third base member 34 is supplied into the processing space S in a shower shape from each of the through holes in the shower plate 35.

The gas supply mechanism 60 includes a gas supply source 62 to supply source gas, a gas supply source 63 to supply reactant gas, and a gas supply source 64 to supply inert gas. For example, bis(diethylamino)silane (BDEAS) gas is used as source Gas of when a SiO₂ film is formed. For example, O₂ (oxygen) gas is used as reactant gas of when the SiO₂ film is formed. As the inert gas, for example, Ar (argon) gas is used. Also, the gas supply mechanism 60 includes a supply regulating unit 65 including a valve, a flow volume controller, and the like. The supply regulating unit 65 regulates supply conditions of the processing gas, such as a gas type, mixing ratio of gas, and flow volume of gas.

The gas supply conditions of which are regulated by the supply regulating unit 65 is supplied to the gas introduction unit 31 of the shower head 30 through a pipe 61a, a pipe 61b, and a pipe 61c. The pipe 61a is connected to a space between the first base member 32 and the second base member 33, the pipe 61b is connected to a space between the second base member 33 and the third base member 34, and the pipe 61c is connected to a space inside the third base member 34. The supply regulating unit 65 can independently regulate supply conditions of the gas supplied to the shower head 30 respectively through the pipe 61a, pipe 61b, and pipe 61c.

A high frequency power source 70 is electrically connected to the shower head 30 via a matching box 71. The high frequency power source 70 generates high frequency power of an arbitrary frequency selected from 100 kHz to 100 MHz, for example. The matching box 71 acts in such a manner that output impedance of the high frequency power source 70 and input impedance of the shower head 30 apparently match each other when plasma is generated in the chamber 10. A wire connecting the matching box 71 and the shower head 30 is covered with a conductor shield cover. The high frequency power source 70 is an example of a plasma generation unit.

A shield cover 50 made of metal is provided on an upper surface of the insulating member 40 in such a manner as to cover the shower head 30. The shield cover 50 is electrically connected to the chamber 10 and is grounded via the chamber 10. The shield cover 50 controls unnecessary high frequency power radiated from the shower head 30 to the outside of the chamber 10.

A temperature regulating unit 51 and a temperature sensor 53 are provided on an upper surface of the shield cover 50, and the temperature regulating unit 51 and the temperature sensor 53 are covered with a heat insulating material 52. The temperature sensor 53 is, for example, an optical fiber thermometer or the like, and measures a temperature of the shower head 30. The temperature regulating unit 51 heats or cools the shower head 30 on the basis of the temperature of the shower head 30, which temperature is measured by the temperature sensor 53, in such a manner that a temperature distribution of the shower head 30 becomes a predetermined temperature distribution. In the present exemplary embodiment, the temperature regulating unit 51 heats the shower head 30 in such a manner that a temperature distribution of the shower head 30 becomes a predetermined temperature distribution. This makes it possible to control a reaction by-product, so-called deposit, which adheres to a lower surface of the shower head 30 due to a film forming process, and to improve uniformity of a process with respect to the wafer W.

An exhaust space 83 is formed between an outer periphery of the insulating member 40 and a side surface of the chamber 10. Also, an exhaust pipe 81 is connected to the side surface of the chamber 10. An exhaust device 80 including a vacuum pump and the like is connected to the exhaust pipe 81 via a pressure regulating valve 82. The exhaust device 80 exhausts the gas in the chamber 10 through the exhaust space 83, the exhaust pipe 81, and the pressure regulating valve 82. The pressure regulating valve 82 regulates a pressure in the chamber 10 by adjusting an amount of exhaust by the exhaust device 80.

An operation of the plasma processing apparatus 1 configured in the above-described manner is comprehensively controlled by a control device 100. The control device 100 includes a processor, a memory, and an input/output interface. For example, the memory stores a program executed by the processor, and a recipe including a condition of each process, and the like. The processor is realized, for example, by a central processing unit (CPU), a digital signal processor (DSP), or the like. The processor executes the program read from the memory, and controls each unit of the plasma processing apparatus 1 via the input/output interface on the basis of the recipe and the like stored in the memory. The processor controls, for example, the lifting/lowering mechanism 14, the heater 20, the temperature regulating unit 51, the supply regulating unit 65, the high frequency power source 70, the matching box 71, the exhaust device 80, the pressure regulating valve 82, and the like.

Note that the program and the like in the memory may be read from a computer-readable storage medium such as a hard disk, flexible disk, compact disk, magnetooptical disk, or memory card and stored into the memory. Also, the program and the like in the memory may be acquired from another device via a communication line and stored into the memory.

Next, the film forming process of a SiO₂ film on a wafer N which process is performed by the plasma processing apparatus 1 will be described. In the film forming process, first, the placing pedestal 11 is lowered below a position of the opening 15 by the lifting/lowering mechanism 14, and the gate valve 16 is opened. Then, the wafer N is carried into the chamber 10 by the transfer arm (not illustrated), placed on the placing pedestal 11, and attracted to and held on the placing pedestal 11. Then, the gate valve 16 is closed and the placing pedestal 11 is lifted to a position illustrated in FIG. 1 by the lifting/lowering mechanism 14. Note that the wafer W is carried into the chamber 10 in a vacuum state by utilization of a load lock chamber or the like.

Next, the heater 20 controls the wafer N to a predetermined temperature, and the temperature regulating unit 51 controls the shower head 30 to a predetermined temperature. The temperature of the wafer N is regulated, for example, to 50 to 100° C., and the temperature of the shower head 30 is regulated, for example, to 100° C. or higher.

Also, O₂ gas and Ar gas of predetermined flow volume are supplied from the gas supply mechanism 60 to the shower head 30, and the gas in the chamber 10 is exhausted by the exhaust device 80. The gas supplied to the shower head 30 diffuses in the shower head 30 in a circumferential direction around the axis X, and is supplied in a shower shape into the chamber 10 from the through holes in the shower plate 35. The supply regulating' unit 65 regulates flow volume of the O₂ gas to approximately 100 to 10000 sccm and flow volume of the Ar gas to approximately 100 to 5000 sccm. Also, an exhaust amount by the exhaust device 80 and an opening degree of the pressure regulating valve 82 are controlled in such a manner that the pressure in the chamber 10 becomes, for example, 50 Pa to 1300 Pa.

When the temperature of the wafer W, the pressure in the chamber 10, and the like become stable, BDEAS gas of predetermined flow volume is supplied from the gas supply mechanism 60 into the chamber 10 for a predetermined period in addition to the above-described O₂ gas and the like. The supply regulating unit 65 regulates the flow volume of the BDEAS gas to approximately 5 to 200 sccm. As a result, molecules of the BDEAS gas are adsorbed on the wafer W (adsorption process). In the present exemplary embodiment, the adsorption process is performed for approximately 0.05 to 1 second.

After the adsorption process of the BDEAS gas, the supply of the BDEAS Gas is stopped and a surface of the wafer P is purged with the O₂ gas and Ar gas (first purge process). As a result, BDEAS molecules excessively adsorbed on the surface of the wafer h are removed. Then, high frequency power is applied to the shower head 30 by the high frequency power source 70, whereby the O₂ gas and Ar Gas supplied into the chamber 10 are turned into plasma. Then, oxygen ions and oxygen radicals activated by the plasma are supplied to the wafer W. As a result, the BDEAS molecules adsorbed on the wafer N are oxidized and SiO₂ molecules are formed (reaction process). In the present exemplary embodiment, the reaction process is performed for approximately 0.2 to 0.5 seconds.

Subsequently, the application of the high frequency power is stopped, and the surface of the wafer N is purged with the O₂ gas and Ar gas (second purge process). As a result, molecules of SiO₂ excessively generated on the surface of the wafer N are removed. Subsequently, the adsorption process, the first purge process, the reaction process, and the second purge process are repeated in this order, whereby a SiO₂ film having a desired film thickness is formed on the wafer W. After the SiO₇ film having the desired film thickness is formed on the wafer N, the wafer N is carried out from the chamber 10. Then, a new wafer N is loaded into the chamber 10, and the series of processes described above is repeated.

Structure of Shower Head 30

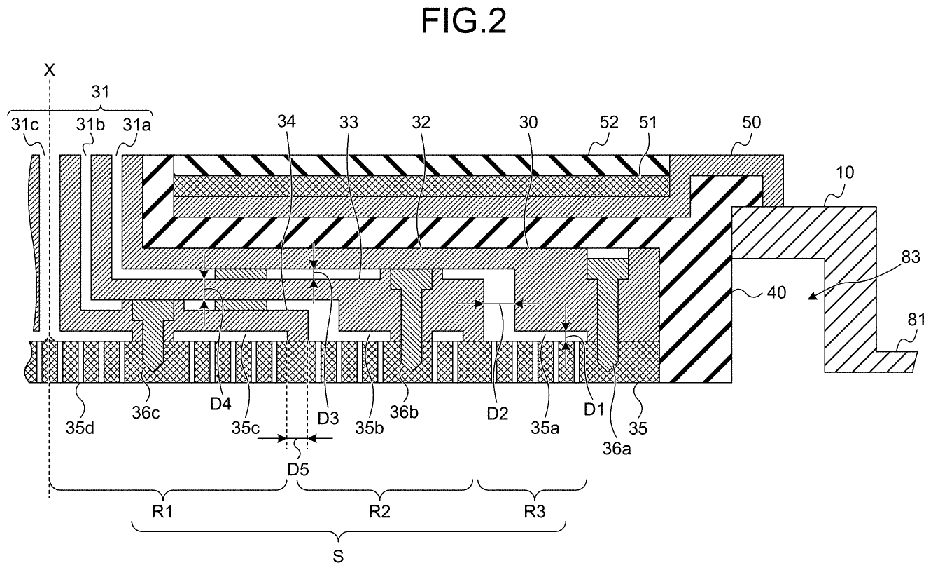

Next, details of the structure of the shower head 30 will be described. FIG. 2 is an enlarged cross-sectional view illustrating an example of the shower head 30 in the first exemplary embodiment.

For example, as illustrated in FIG. 2, the shower head 30 includes a first base member 32, a second base member 33, a third base member 34, and a shower plate 35. The second base member 33 is arranged in a space surrounded by the first base member 32 and the shower plate 35, and the third base member 34 is arranged in a space surrounded by the second base member 33 and the shower plate 35. The first base member 32 is fixed to the shower plate 35 by screws 36a, the second base member 33 is fixed to the shower plate 35 by screws 36b, and the third base member 34 is fixed to the shower plate 35 by screws 36c. The screws 36a, screws 36b, and screws 36c are preferably made of a material that has a high thermal conductivity and that is, for example, a nickel alloy such as stainless steel, or titanium.

The gas introduction unit 31 includes gas introduction ports 31a to 31c. The gas introduction port 31a supplies the gas, which is supplied from the supply regulating unit 65 through the pipe 61a, into a space formed between the first base member 32 and the second base member 33. The gas supplied into the space formed between the first base member 32 and the second base member 33 flows in a direction of moving away from the axis X while diffusing in a circumferential direction of a circle centered on the axis X. Then, the gas that diffuses in the space formed between the first base member 32 and the second base member 33 further diffuses in a space 35a formed among the first base member 32, the second base member 33, and the shower plate 35. Then, the as that diffuses in the space 35a is supplied in a shower shape into the processing space S through a plurality of through holes 35d formed in the shower plate 35. The gas that. diffuses in the space 35a is supplied to the outermost peripheral region R3 among regions in the wafer W placed on the placing pedestal 11.

The gas introduction port 31b supplies the gas, which is supplied from the supply regulating unit 65 through the pipe 61b, into a space formed between the second base member 33 and the third base member 34. The gas supplied into the space formed between the second base member 33 and the third base member 34 flows in a direction of moving away from the axis X while diffusing in the circumferential direction of the circle centered on the axis X. Then, the gas that diffuses in the space formed between the second base member 33 and the third base member 34 further diffuses in a space 35b formed among the second base member 33, the third base member 34, and the shower plate 35. Then, the gas that diffuses in the space 35b is supplied in a shower shape into the processing space S through the plurality of through holes 35d formed in the shower plate 35. The gas that diffuses in the space 35b is supplied to a region R2, which is between a region R1 near a center of the wafer K and the outermost peripheral region R3, among the regions in the wafer W placed on the placing pedestal 11.

The gas introduction port 31c supplies the gas, which is supplied from the supply regulating unit 65 through the pipe 61c, into a space formed in the third base member 34. The gas supplied into the space in the third base member 34 flows i.n a direction of the shower plate 35 along the axis x. Then, the gas flowing in the direction of the shower plate 35 along the axis X further diffuses in the circumferential direction of the circle centered on the axis X in a space 35c formed between the third base member 34 and the shower plate 35. Then, the gas that diffuses in the space 35c supplied in a shower shape into the processing space S through the plurality of through holes 35d formed in the shower plate 35. The gas that diffuses in the space 35c is supplied to the region R1 near the center of the wafer W among the regions in the wafer K placed on the placing pedestal 11.

Here, shapes of the first base member 32, the second base member 33, and the third base member 34 included in the shower head 30 will be described in more detail.

Structure of First Base Member 32

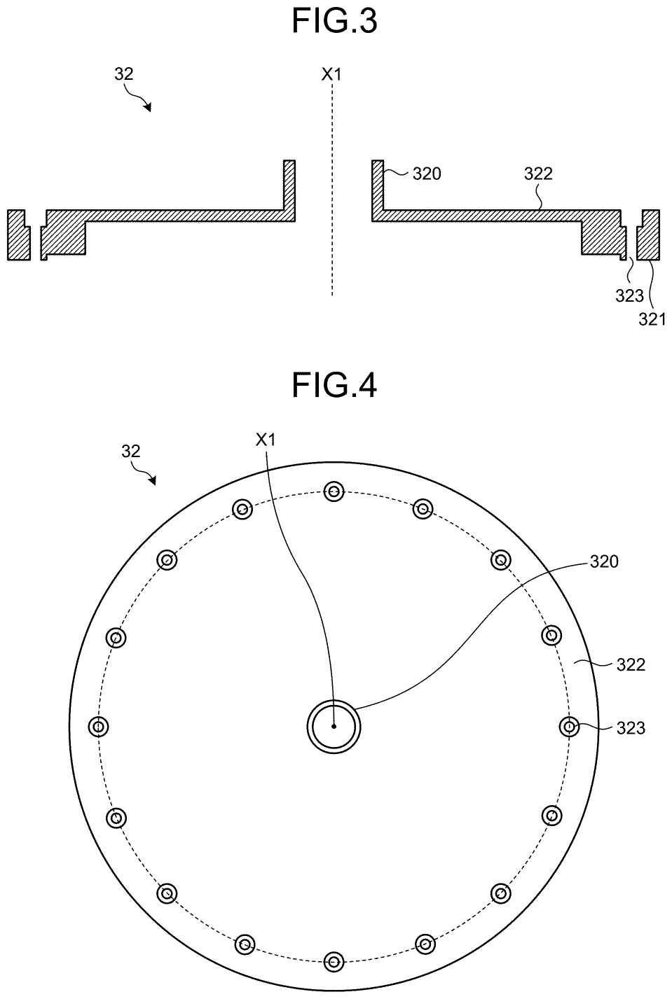

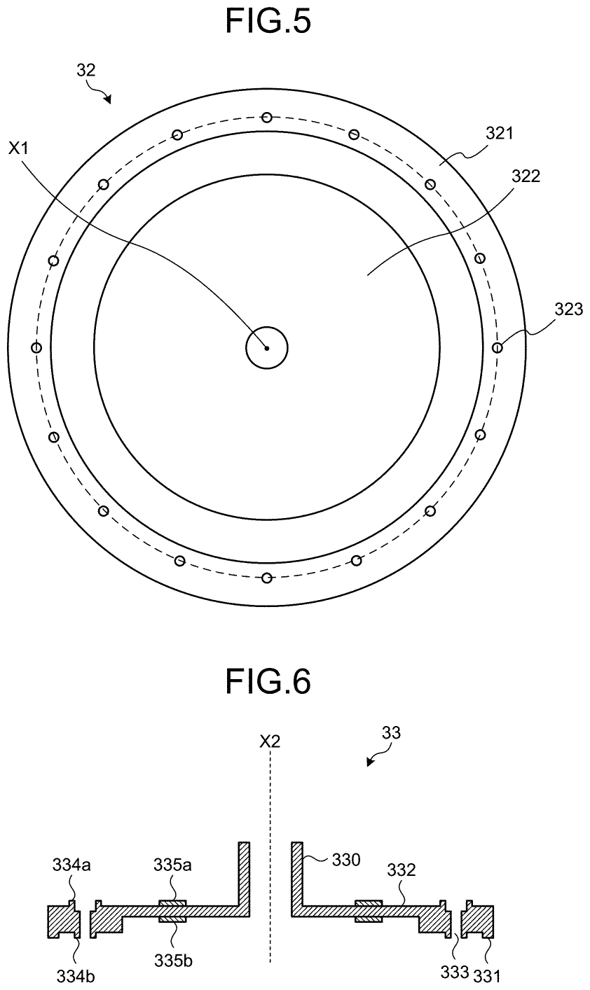

FIG. 3 is a cross-sectional view illustrating an example of the first base member 32. FIG. 4 is a top view illustrating the example of the first base member 32. FIG. 5 is a bottom view illustrating the example of the first base member 32.

The first base member 32 has a cylindrical wall 320, a cylindrical wall 321, and an upper wall 322, for example, as illustrated in FIG. 3. The cylindrical wall 320 i.s an example of a first cylindrical wall, the cylindrical wall 321 is an example of a second cylindrical wall, and the upper wall 322 is an example of a first upper wall.

The cylindrical wall 320 has a hollow cylindrical shape. A central axis of the cylindrical wall 320 is defined as an axis X1. The cylindrical wall 321 has a. cylindrical shape coaxial with the cylindrical wall 320. Also, a diameter of the cylindrical wall 321 is larger than a diameter of the cylindrical wall 320 in a cross section intersecting with the axis X1. The upper wall 322 has a substantially disk shape centered on the axis X1, and connects a lower end of the cylindrical wall 320 and an upper end of the cylindrical wall 321. That is, the cylindrical wall 320 is extended in a first direction along the axis X1 from a vicinity of the axis X1 of the upper wall 322, and the cylindrical wall 321 is extended in a direction opposite to the first direction along the axis X1 from an outer peripheral part of the upper wall 322.

A plurality of threaded holes 323 is formed in the cylindrical wall 321. For example, as illustrated in FIG. 4 and FIG. 5, the plurality of threaded holes 323 is arranged at equal intervals on a circumference centered on the axis X1. The first base member 32 is fixed to the shower plate 35 by the screws 36a inserted into the respective threaded holes 323. Thus, heat transferred from the temperature regulating unit 51 to the first base member 32 is transferred to the shower plate 35 through the screws 36a that fix the first base member 32 and the shower plate 35, and a lower end of the cylindrical wall 321 that is in contact with the shower plate 35.

Structure of Second Base Member 33

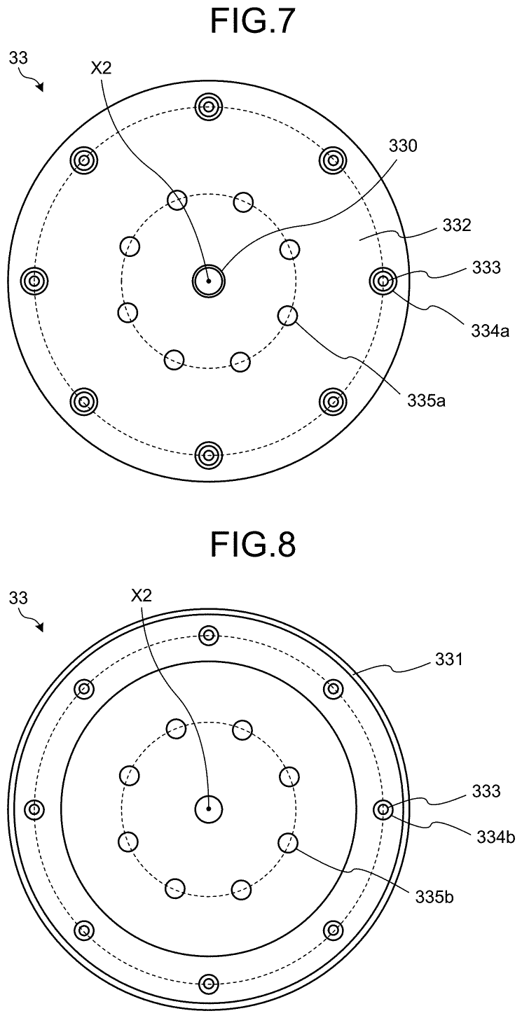

FIG. 6 is a cross-sectional view illustrating an example of the second base member 33. FIG. 7 is a top view illustrating the example of the second base member 33. FIG. 8 is a bottom view illustrating the example of the second base member 33.

For example, as illustrated in FIG. 6, the second base member 33 has a cylindrical wall 330, a cylindrical wall. 331, and an upper wall 332. The cylindrical wall 330 is an example of a third cylindrical wall, the cylindrical wall 331 is an example of a fourth cylindrical wall, and the upper wall 332 an example of a second upper wall.

The cylindrical wall 330 has a hollow cylindrical shape. A central axis of the cylindrical wall 330 is defined as an axis X2. A diameter of the cylindrical wall 330 in a cross section intersecting with the axis X2 is smaller than the diameter of the cylindrical wall 320 of the first base member 32 in the cross section intersecting with the axis X1. In a case of being assembled as the shower head 30, the cylindrical wall 330 is arranged in a space, which is surrounded by the cylindrical wall 320, in such a manner that the axis X2 of the second base member 33 and the axis X1 of the first base member 32 coincide with each other. That as, an a state in which assembling as the shower head 30 is performed, the axis X2 of the cylindrical wall 330 of the second base member 33 and the axis X1 of the cylindrical wall 320 of the first base member 32 coincide with each other.

The cylindrical wall 331 has a cylindrical shape coaxial with the cylindrical wall 330. Also, a diameter of the cylindrical wall 331 is larger than the diameter of the cylindrical wall 330 in the cross section intersecting with the axis X2. The upper wall 332 has a substantially disk shape centered on the axis X2, and connects a lower end of the cylindrical wall 330 and an upper end of the cylindrical wall 331. That is, the cylindrical wall 330 is extended in a second direction along the axis X2 from a vicinity of the axis X2 of the upper wall 332, and the cylindrical wall 331 is extended in a direction opposite to the second direction along the axis X2 from an outer peripheral part of the upper wall 332.

A plurality of threaded holes 333 is formed in the upper wall 332. For example, as illustrated in FIG. 7 and FIG. 8, the plurality of threaded holes 333 is arranged at equal intervals on a circumference centered on the axis X2. In each of the threaded holes 333, a cylindrical rib 334a is provided, in such a manner as to surround the threaded hole 333, on a surface of the upper wall 332 which surface is on a side of the cylindrical wall 330. Also, in each of the threaded holes 333, a cylindrical rib 334b is provided, in such a manner as to surround the threaded hole 333, on a surface of the upper wall 332 which surface is on a side of the cylindrical wall 331.

Also, a plurality of protrusions 335a is provided on the surface of the upper wall 332 which surface is on the side of the cylindrical wall 330, and a plurality of protrusions 335b is provided on the surface of the upper wall 332 which surface is on the side of the cylindrical wall. 331. For example, as illustrated in FIG. 7 and FIG. 8, the plurality of protrusions 335a and 335b is arranged at equal intervals on a circumference centered on the axis X2.

In the present exemplary embodiment, a shape of each of the protrusions 335a and 335b viewed in a direction of the axis X2 is a substantially circular shape. Thus, it is possible to prevent a flow of the gas supplied to the space between the first base member 32 and the second base member 33 from being blocked by the protrusions 335a. Similarly, it is possible to prevent a flow of the gas supplied to the space between the second base member 33 and the third base member 34 from being blocked by the protrusions 335b. Note that a shape of each of the protrusions 335a and 335b viewed in the direction of the axis X2 may be an elliptical or plate-like shape as long as a flow of the gas is not blocked. However, in a case where an elliptical or plate-like shape is adopted as the shape of the protrusions 335a and 335b, the protrusions 335a and 335b are preferably arranged in such a manner that a longitudinal direction is along a direction getting away from the axis X2.

In a case of being assembled as the shower head 30, the ribs 334a and the protrusions 335a come into contact with a lower surface of the upper wall 322 of the first base member 32, for example, as illustrated in FIG. 2. As a material of the ribs 334a and the protrusions 335a, a material similar to the material of the shower head 30, such as aluminum or nickel is used. Thus, heat of the first base member 32 is efficiently transferred to the second base member 33 via the ribs 334a and the protrusions 335a. Also, in a case of being assembled as the shower head 30, the protrusions 335b come into contact with the third base member 34, for example, as illustrated in. FIG.

Thus, heat of the second base member 33 is efficiently transferred to the third base member 34 via the protrusions 335b. The ribs 334a, the protrusions 335a, and the protrusions 335b are examples of a heat transfer member.

Structure of Third Base Member 34

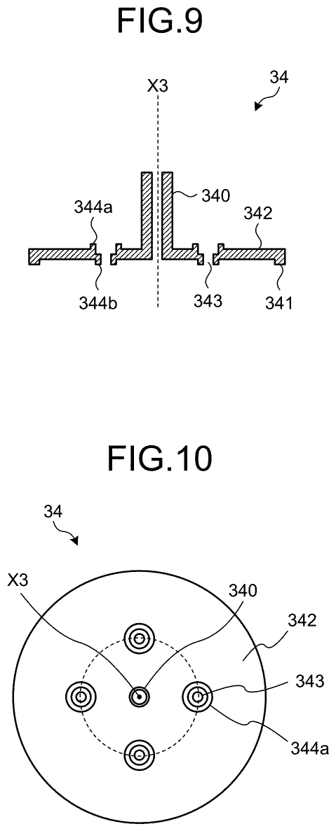

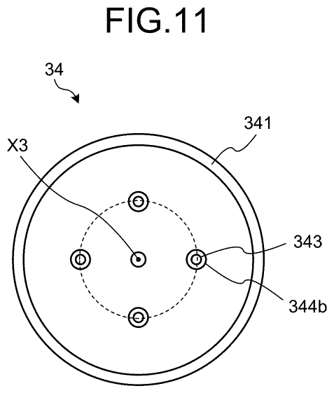

FIG. 9 is a cross-sectional view illustrating an example of the third base member 34. FIG. 10 is a top view illustrating the example of the third base member 34. FIG. 11 is a bottom view illustrating the example of the third. base member 34.

For example, as illustrated in FIG. 9, the third base member 34 has a cylindrical wall 340, a cylindrical wall 341, and an upper wall 342. The cylindrical wall 340 has a hollow cylindrical shape. A central axis of the cylindrical wall 340 is defined as an axis X3. A diameter of the cylindrical wall 340 in a cross section intersecting with the axis X3 is smaller than the diameter of the cylindrical wall 330 of the second base member 33 in the cross section intersecting with the axis X2. In a case of being assembled as the shower head 30, the third base member 34 is arranged in a space, which is surrounded by the cylindrical wall 330, in such a manner that the axis X3 of the third base member 34 and the axis X2 of the second base member 33 coincide with each other. That is, in a state in which assembling as the shower head 30 is performed, the axis X3 of the cylindrical wall 340 of the third base member 34, the axis X2 of the cylindrical wall 330 of the second base member 33, and the axis X1 of the cylindrical wall 320 of the first base member 32 coincide with each other.

The cylindrical wall 341 has a cylindrical shape coaxial with the cylindrical wall 340. Also, a diameter of the cylindrical wall 341 is larger than the diameter of the cylindrical wall 340 in the cross section intersecting with the axis X3. The upper wall 342 has a substantially disk shape centered on the axis X3, and connects a lower end of the cylindrical wall 340 and an upper end of the cylindrical wall 341. That is, the cylindrical wall 340 is extended in a third direction along the axis X3 from a vicinity of the axis X3 of the upper wall 342, and the cylindrical wall 341 is extended in a direction opposite to the third direction along the axis X3 from an outer peripheral part of the upper wall 342.

A plurality of threaded holes 343 is formed in the upper wall 342. For example, as illustrated in FIG. 10 and FIG. 11, the plurality of threaded holes 343 is arranged at equal intervals on a circumference centered on the axis X3. In each of the threaded holes 343, a cylindrical rib 344a is provided, in such a mariner as to surround the threaded hole 343, on a surface of the upper wall 342 which surface is on a side of the cylindrical wall 340. Also, in each of the threaded holes 343, a cylindrical rib 344b is provided, in such a manner as to surround the threaded hole 343, on a surface of the upper wall 342 which surface is on a side of the cylindrical wall 341.

In a case of being assembled as the shower head 30, the protrusions 335b of the second base member 33 come into contact with an upper surface of the upper wall 342 of the third base member 34, for example, as illustrated in FIG. 2. Also, in a case of being assembled as the shower head 30, the ribs 344a of the third base member 34 come into contact with a lower surface of the upper wall 332 of the second base member 33, for example, as illustrated in FIG. 2. Thus, heat of the second base member 33 is efficiently transferred to the third base member 34 via the protrusions 335b and the ribs 344a. Also, in a case of being assembled as the shower head 30, the ribs 344b come into contact with the shower plate 35, for example, as illustrated in FIG. 2. Thus, heat of the third base member 34 is efficiently transferred to the shower plate 35 via the ribs 344b.

Here, between the first base member 32 and the second base member 33, and between the second base member 33 and the third base member 34, spaces to diffuse the gas supplied from the gas supply mechanism 60 are respectively formed. Thus, in a case where the ribs 334a and the protrusions 335a. are not provided on the second base member 33, the heat of the first base member 32 is not directly transferred to the second base member 33. Also, in a case where the ribs 334b are not provided on the second base member 33 and the ribs 344a are not provided on the third base member 34, the heat of the second base member 33 is not directly transferred to the third base member 34. Thus, even when the temperature regulating unit 51 controls a temperature distribution of the first base member 32, it is difficult to control the shower plate 35 to have a desired temperature distribution.

On the other hand, in the shower head. 30 of the present exemplary embodiment, the ribs 334a and the protrusions 335a are provided on the second base member 33. Thus, the heat of the first base member 32 is directly transferred to the second base member 33 via the ribs 334a and the protrusions 335a. Also, in the shower head 30 of the present exemplary embodiment, the heat of the second base member 33 is directly transferred to the third base member 34 since the protrusions 335b are provided on the second base member 33. Furthermore, in the shower head 30 of the present exemplary embodiment, the ribs 344a are provided on the third base member 34. Thus, the heat of the second base member 33 is more efficiently transferred to the third base member 34. Thus, the shower plate 35 can be controlled to have a desired temperature distribution according to a temperature distribution of the first base member 32 controlled by the temperature regulating unit 51.

Note that a width D1 of the space 35a (see FIG. 2) is preferably small in order to uniformly process the wafer N in the plane. However, when the width as too small, uniformity of processing on the wafer N is decreased. In the present exemplary embodiment, the width D1 of the space 35a is preferably a width within a range of 2 to 7 mm, for example. Note that the width D1 of the space 35a is more preferably 2 mm, for example. The same applies to widths of the space 35b and the space 35c.

Also, a width D2 of a space between the cylindrical wall 321 of the first base member 32 and the cylindrical wall 331 of the second base member 33 (see FIG. 2) is preferably smaller than a predetermined thickness in order to improve uniformity of processing on the wafer W. In the present exemplary embodiment, the width D2 is preferably a width of 6 mm or smaller, for example. The same applies to a width of a space between the cylindrical wall 331 of the second base member 33 and the cylindrical wall 341 of the third base member 34.

A width D3 of a space between the upper wall 322 of the first base member 32 and the upper wall 332 of the second base member 33 (see FIG. 2) is preferably smaller in order to improve uniformity of processing on the wafer W. In the present exemplary embodiment, the width D3 is preferably a width within the range of 1.5 mm to 5 mm, for example. Note that the width D3 is more preferably 2 mm, for example. The same applies to a width of a space between the upper wall 332 of the second base member 33 and the upper wall 342 of the third base member 34.

A thickness D4 of the upper wall 332 of the second base member 33 (see FIG. 2) is preferably small in order to reduce a size of the shower head 30 as a device. The same applies to a thickness of the upper wall 342 of the third base member 34. A thickness D5 of the cylindrical wall 341 of the third base member 34 (see FIG. 2) is preferably small in order to improve uniformity of processing on the wafer W.

The first exemplary embodiment has been described above. A plasma processing apparatus 1 of the present exemplary embodiment includes a chamber 10, a placing pedestal 11 which is arranged in the chamber 10 and on which a wafer d is placed, and a shower head 30 that is arranged at a position facing the placing pedestal 11 and that supplies gas into the chamber 10. The shower head 30 has a first base member 32, a second base member 33, a shower plate 35, and a plurality of protrusions 335a. The first base member 32 has a cylindrical wall 320, a cylindrical wall 321, and an upper wall 322. The cylindrical wall 320 has a cylindrical shape. The cylindrical wall 321 has a cylindrical shape coaxial with the cylindrical wall 320 and has a larger diameter than the cylindrical wall 320. The upper wall 322 connects a lower end of the cylindrical wall 320 and an upper end of the cylindrical wall 321. The second base member 33 has a cylindrical wail 330, a cylindrical wall 331, and an upper wall. 332. The cylindrical wall. 330 has a cylindrical shape coaxial with the cylindrical wall 320, has a smaller diameter than the cylindrical wall 320, and is arranged in a space surrounded by the cylindrical wall 320. The cylindrical wall 331 has a cylindrical shape coaxial with the cylindrical wall 320, has a diameter larger than that of the cylindrical wall. 330 and smaller than that of the cylindrical wall 321, and is arranged in a space surrounded by the cylindrical wall 321. The upper wall 332 is arranged below the upper wall 322, and connects a lower end of the cylindrical wall 330 and an upper end of the cylindrical wall 331. The shower plate 35 has a plurality of through holes 35d and is arranged at a lower end of the cylindrical wall 321 and a lower end of the cylindrical wall 331. Each of the protrusions 335a is arranged between the upper wall 322 and the upper wall 332, and is in contact with a lower surface of the upper wall 322 and an upper surface of the upper wall 332. Thus, it is possible to control a temperature distribution of the shower head 30 accurately.

Also, in the above-described exemplary embodiment, the plurality of protrusions 335a is arranged at equal intervals between the upper wall 322 and the upper wall 332 in a circumferential direction of a circle centered on an axis X of the cylindrical wall 320. Thus, it is possible to control a deviation of a gas flow between the upper wall 322 and the upper wall 332.

Also, in the above-described exemplary embodiment, a temperature regulating unit 51 that controls a temperature distribution of the shower head 30 is provided above the shower head 30. Thus, the temperature distribution of the shower head 30 can be controlled accurately.

Also, in the above-described exemplary embodiment, the shower head 30 is made of a conductor. Also, in the above-described exemplary embodiment, the plasma processing apparatus 1 includes a high frequency power source 70 and a shield cover 50. By supplying high frequency power to the shower head 30, the high frequency power source 70 generates plasma of the gas supplied from the shower head 30 into the chamber 10. The shield cover 50 is made of a conductor, is provided above the shower head 30 in such a manner as to cover the shower head 30, and is grounded. Thus, unnecessary high frequency power radiated from the shower head 30 to the outside of the chamber 10 is blocked.

### Second Exemplary Embodiment

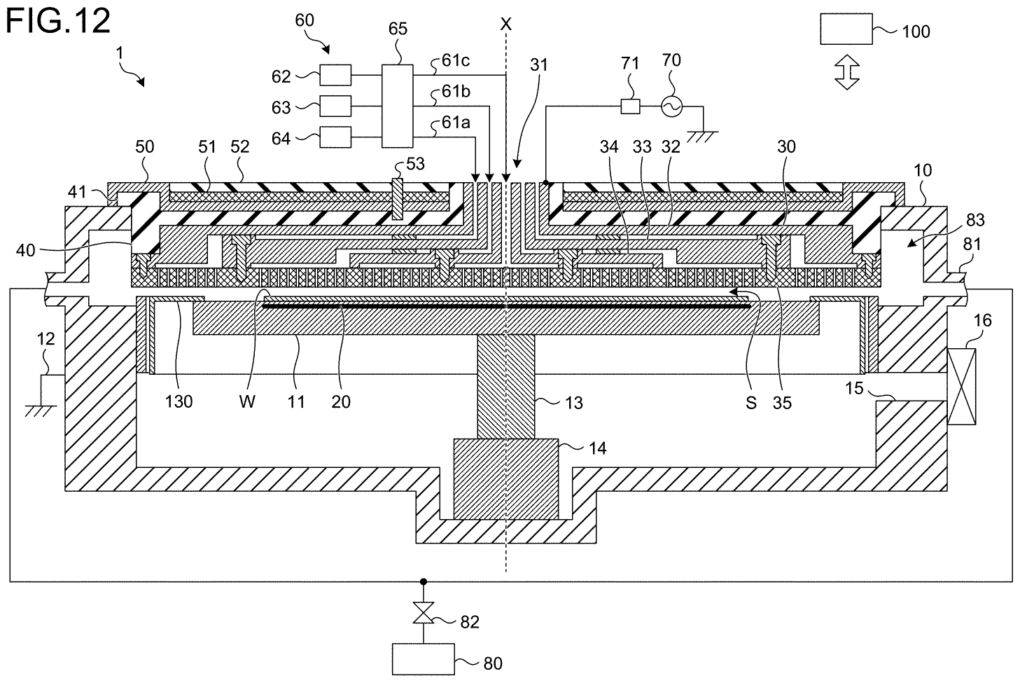

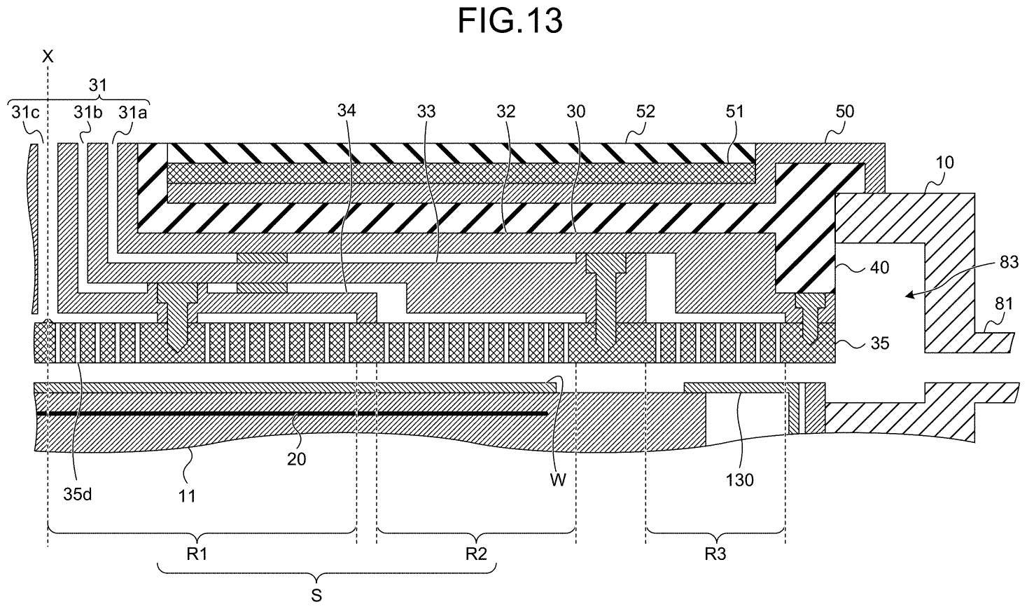

Structure of plasma processing apparatus 1 FIG. 12 is a schematic cross-sectional view illustrating an example of the plasma processing apparatus 1 in the second exemplary embodiment of the present disclosure. Note that since configurations to which reference signs the same as those in FIG. 1 are assigned are similar to the configurations described in FIG. 1 except for a point described below, detailed description thereof will be omitted in FIG. 12. In the plasma processing apparatus 1 in the present exemplary embodiment, gas supplied into a third base member 34 and gas supplied between a second base member 33 and a third base member 34 are supplied to regions in a wafer W. On the one hand, in the plasma processing apparatus 1 in the present exemplary embodiment, gas supplied between a first base member 32 and the second base member 33 is supplied to a region outside the regions in the wafer W.

Structure of Shower Head 30

FIG. 13 is an enlarged cross-sectional view illustrating an example of the shower head 30 in the second exemplary embodiment. Note that since configurations to which reference signs the same as those in FIG. 2 are assigned are similar to the configurations described in FIG. 2 except for points described below, detailed description thereof will be omitted in FIG. 13. In the present exemplary embodiment, gas supplied between the first base member 32 and the second base member 33 is supplied to a region R3 that is a region outside the regions in the wafer N through the through holes 35d, for example, as illustrated in FIG. 13. Also, in the present exemplary embodiment, a side surface of the shower head 30 is not covered with an insulating member 40, and side surfaces of the first base member 32 and a shower plate 35 are exposed to an exhaust space 83 in a chamber 10. Thus, a part of high frequency power that is applied from a high frequency power source 70 to the shower head 30 and that propagates on a surface of the first base member 32 is radiated from the side surface of the first base member 32 and the side surface of the shower plate 35 to the exhaust space 83.

Also, the gas supplied into the chamber 10 through the through holes 35d in the shower plate 35 passes through the exhaust space 83 and is exhausted from an exhaust pipe 81. Thus, when passing through the exhaust space 83, the gas supplied from the through holes 35d in the shower plate 35 is turned into plasma by the high frequency power radiated from the side surface of the shower head 30 into the exhaust space 83. Then, a reaction by-product, so-called deposit, adhered to a surface of the chamber 10 is removed in the exhaust space 83 by active species contained in the plasma.

In the plasma processing apparatus 1 in the present exemplary embodiment, predetermined gas is supplied to a region R1 and a region R2 in each of an adsorption process, a first purge process, a reaction process, and a second purge process in a case where a film forming process is performed. On the one hand, in the plasma processing apparatus 1 in the present exemplary embodiment, in a case where the film forming process is performed, inert gas such as Ar gas is supplied to the region R3 from a through hole 35d above the region R3, or gas is not supplied thereto. Also, in a cleaning process for removing the deposit in the chamber 10, gas for cleaning is supplied to the region R3 from the through hole 35d above the region R3. For example, ClF₃ gas, NF ₃ gas, or the like is used as the gas for cleaning.

Note that in the cleaning process, inert gas such as Ar gas may be supplied to the region R1 and region R2 in order to generate a flow of the gas from the region R1 and region R2 to the region R3. As a result, it is possible to prevent particles removed from the exhaust space 83 by the cleaning from entering the region R1 and region R2. Also, in order to protect a placing pedestal 11, a dummy wafer may be placed at a position where a wafer W is arranged in the cleaning process. Also, in the cleaning process, a purpose is to remove the deposit in the exhaust space 83. Thus, it is only necessary that plasma is generated in the exhaust space 83. Thus, it is preferable that flow volume of gas, a pressure in the chamber 10, magnitude of the high frequency power, and the like are regulated in such a manner that plasma is not generated in the regions R1 to R3. Also, in order to prevent generation of plasma in the regions R1 to R3, the placing pedestal 11 serving as an opposite electrode of the shower head 30 may be lowered. Note that by moving the placing pedestal. 11 away from the shower head 30, it is also possible to acquire an effect that coupling of a wall surface of the chamber 10 and the shower head 30 that is an upper electrode becomes easier.

The second exemplary embodiment has been described above. In a plasma processing apparatus 1 of the present exemplary embodiment, a side surface of a cylindrical wall 321 of a first base member 32 is exposed to an inner side wall of a chamber 10. Also, through a plurality of through holes 35d included in the shower plate 35, gas supplied between the first base member 32 and a second base member 33 is discharged to a region on the outside of regions in a wafer N placed on a placing pedestal 11. Thus, it is possible to execute a film forming process and cleaning of a side wall of the chamber 10 with a plasma processing apparatus 1 having the same configuration.

### Third Exemplary Embodiment

Structure of Shower Head 30

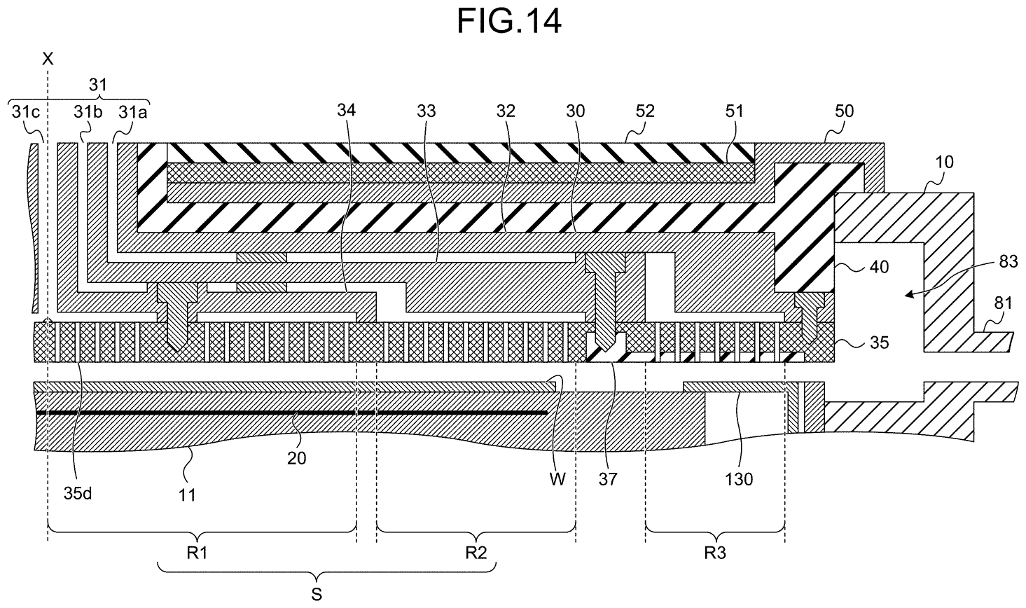

FIG. 14 is an enlarged cross-sectional view illustrating an example of the shower head 30 in the third exemplary embodiment. Note that since configurations to which reference signs the same as those in FIG. 2 or FIG. 13 are assigned are similar to the configurations described in FIG. 2 or FIG. 13 except for points described below, detailed description thereof will be omitted in FIG. 14. Also, since an overall configuration of the plasma processing apparatus 1 is similar to that of the plasma processing apparatus 1 in the second exemplary embodiment. described with reference to FIG. 12 except for points described below, description thereof is omitted.

For example, as illustrated in FIG. 14, in the present exemplary embodiment, a point that a cover member 37 is provided on a lower surface of a shower plate 35 in a region R3, to which gas between a first base member 32 and a second base member 33 is supplied, is different from the second exemplary embodiment. The cover member 37 is formed of a dielectric material such as quartz.

In the plasma processing apparatus 1 in the present exemplary embodiment, the cover member 37 is provided on the lower surface of the shower plate 35 in the region R3, whereby high frequency power radiated from the lower surface of the shower plate 35 to the region R3 can be controlled. Thus, generation of plasma in the region R3 can be controlled, and damage on a member such as a cover member 130 arranged in the region R3 can be controlled in a cleaning process.

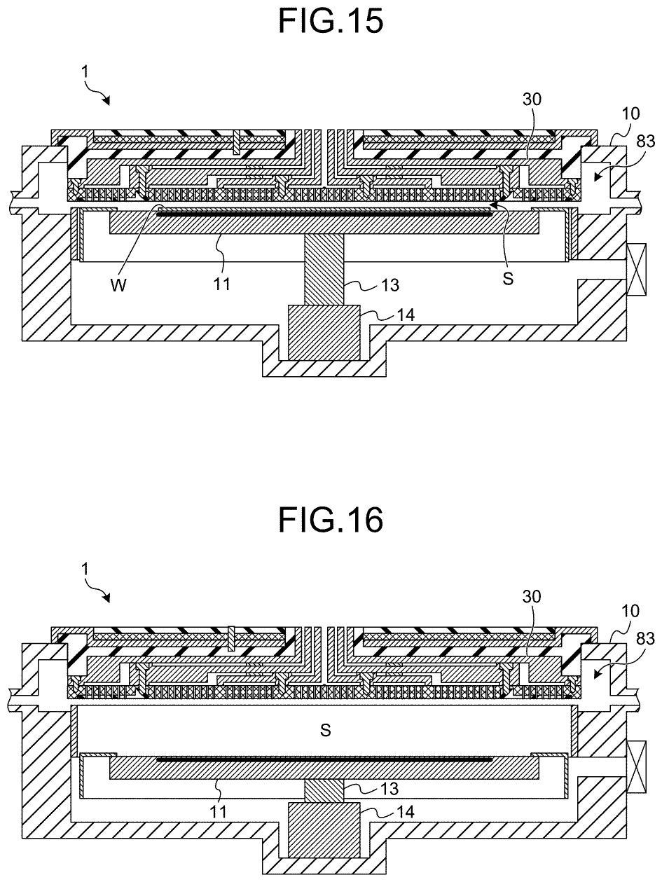

Note that in the plasma processing apparatus 1 in the present exemplary embodiment, in a case where a film forming process is performed, a placing pedestal 11 is lifted to a position close to the shower head 30 by a lifting/lowering mechanism 14, for example, as illustrated in FIG. 15. Then, flow volume of gas, a pressure in the chamber 10, magnitude of the high frequency power, and the like are regulated in such a manner that a condition with which plasma is likely to be generated in a processing space S is acquired. Also, in the plasma processing apparatus 1 in the present exemplary embodiment, in a case where cleaning of the inside of the chamber 10 is performed, the placing pedestal 11 may be lowered to a position away from the shower head 30 by the lifting/lowering mechanism 14, for example, as illustrated in FIG. 16. Then, flow volume of gas, a pressure in the chamber 10, magnitude of the high frequency power, and the like are regulated in such a manner that a condition with which plasma is not likely to be generated in the processing space S and plasma is likely to be generated in an exhaust space 83 is acquired. Note that in a case where cleaning of the inside of the chamber 10 is performed, a dummy wafer may be placed on the placing pedestal 11 to protect the placing pedestal 11.

The third exemplary embodiment has been described above. In a plasma processing apparatus 1 of the present exemplary embodiment, a cover member 37 formed of a dielectric material is provided on a lower surface of a shower plate 35 between a lower end of a cylindrical wall 331 and a lower end of a cylindrical wall 321. Thus, high frequency power radiated to a region R3 below the shower plate 35 which region corresponds to a region between the lower end of the cylindrical wall 331 and the lower end of the cylindrical wall 321 is controlled. Thus, it is possible to control damage on a member placed in the region R3 when cleaning of the inside of the chamber 10 is performed.

Other

Note that a technology disclosed in the present application is not limited to the above-described exemplary embodiment, and various modifications can be made within the scope of the gist.

For example, although a plasma processing apparatus 1 has been described as an example of a substrate processing apparatus in each of the above-described exemplary embodiments, the disclosed technology is not limited thereto. For example, the disclosed technology can be also applied to an apparatus that does not use plasma as long as the apparatus is an apparatus to perform processing on a wafer W by using gas and to control a temperature distribution of a shower head 30 that supplies the gas to the wafer W.

Also, although capacitively coupled plasma (CCP) has been described as an example of a plasma generation method in each of the above-described exemplary embodiments, the disclosed technology is not limited thereto. For example, the disclosed technology can be also applied to a plasma processing apparatus that is an apparatus to perform processing on a wafer P by using gas and to control a temperature distribution of a shower head 30 that supplies the gas to the wafer W.

Also, although protrusions 335a and 335b are provided on an upper wall 332 of a second base member 33 in each of the above-described exemplary embodiments, the disclosed technology is not limited thereto. For example, a protrusion 335a may be provided on a lower surface of an upper wall 322 of a first base member 32, and a protrusion 335b may be provided on an upper surface of an upper wall 342 of a third base member 34.

Also, although protrusions 335a and 335b are formed on an upper wall 332 of a second base member 33 in a manner of being integral with the upper wall 332 in each of the above-described exemplary embodiments, the disclosed technology is not limited thereto. For example, protrusions 335a and 335b may be configured as members different from a second base member 33, and attached to the second base member 33.

Also, although gas is supplied downward from a shower plate 35 in a region R3 in the third exemplary embodiment described above, the disclosed technology is not limited thereto. For example, no through hole 35d may be provided at a position in a shower plate 35 which position corresponds to a region R3, and a plurality of through holes 35d may be provided in a side surface of an outer peripheral part of a first base member 32 or a side surface of an outer peripheral part of the shower plate 35. Alternatively, a plurality of through holes 35d may be provided in a side surface of a joint between a first base member 32 and a shower plate 35. As a result, gas supplied between the first base member 32 and the shower plate 35 is discharged not toward the region R3 but toward an exhaust 83. Thus, in a cleaning process, it becomes easier to create a condition with which plasma is likely to be generated in the exhaust space 83, and it is possible to efficiently remove a deposit in the exhaust space 83.

Also, although a shower head 30 has three base members in each of the above-described exemplary embodiments, the disclosed technology is not limited thereto. A shower head 30 may have two base members, or have four or more base members.

Also, although an upper wall of each base member and a shower plate 35 are arranged to be parallel in each of the above-described exemplary embodiments, the disclosed technology is not limited thereto. For example, an upper wall of each base member may be inclined in such a manner that a height is increased or decreased as a distance from an axis X is increased.

Note that it is to be considered that the exemplary embodiments disclosed this time are exemplifications in all points and are not restrictions. Indeed, the above-described exemplary embodiments may be embodied in various forms. Also, the above-described exemplary embodiments may be omitted, replaced, or modified in various forms without departing from the spirit and scope of the accompanying claims.

According to various aspects and exemplary embodiments of the present disclosure, it is possible to accurately control a temperature distribution of a shower head.

What is claimed is:

1. A substrate processing apparatus comprising:
a chamber;
a placing pedestal which is arranged in the chamber and on which a substrate to be processed is placed; and
a shower head that is arranged at a position facing the placing pedestal and that supplies gas into the chamber, wherein
the shower head includes a first base member, a second base member, a shower plate, and a plurality of heat transfer members,
the first base member includes
a first cylindrical wall having a cylindrical shape,
a second cylindrical wall having a cylindrical shape coaxial with the first cylindrical wall, and having a larger diameter than the first cylindrical wall, and
a first upper wall connecting a lower end of the first cylindrical wall and an upper end of the second cylindrical wall,
the second base member includes
a third cylindrical wall having a cylindrical shape coaxial with the first cylindrical wall, having a smaller diameter than the first cylindrical wall, and arranged in a space surrounded by the first cylindrical wall,
a fourth cylindrical wall having a cylindrical shape coaxial with the first cylindrical wall, having a larger diameter than the third cylindrical wall, having a smaller diameter than the second cylindrical wall, and arranged in a space surrounded by the second cylindrical wall, and
a second upper wall arranged below the first upper wall, and connecting a lower end of the third cylindrical wall and an upper end of the fourth cylindrical wall,
the shower plate includes a plurality of through holes, and is arranged at a lower end of the second cylindrical wall and a lower end of the fourth cylindrical wall, and
each of the heat transfer members is arranged between the first upper wall and the second upper wall and is in contact with a lower surface of the first upper wail and an upper surface of the second upper wall.

2. The substrate processing apparatus according to claim 1, wherein
the plurality of heat transfer members is arranged at equal intervals between the first upper wall and the second upper wall in a circumferential direction of a circle centered on an axis of the first cylindrical wall.

3. The substrate processing apparatus according to claim 1, further comprising
a temperature regulating unit that is provided above the shower head and that regulates a temperature distribution of the shower head.

4. The substrate processing apparatus according to claim 1, wherein
the shower head is made of a conductor, and
the substrate processing apparatus further comprises
a plasma generation unit that generates plasma of the gas, which is supplied from the shower head into the chamber, by supplying high frequency power to the shower head, and
a shield cover that is made of a conductor, provided above the shower head in such a manner as to cover the shower head, and grounded.

5. The substrate processing apparatus according to claim 4, wherein
a side surface of the second cylindrical wall is exposed to an inner side wall of the chamber,
gas supplied between the first base member and the second base member is discharged to a region outside a region in the substrate to be processed, which substrate is placed on the placing pedestal, through the plurality of through holes in the shower plate.

6. The substrate processing apparatus according to claim 5, wherein
a cover member formed of a dielectric material is provided on a lower surface of the shower plate between the lower end of the fourth cylindrical wall and the lower end of the second cylindrical wall.

7. A shower head comprising:
a first base member;
a second base member;
a shower plate; and
a plurality of heat transfer members, wherein
the first base member includes
a first cylindrical wall having a cylindrical shape,
a second cylindrical wall having a cylindrical shape coaxial with the first cylindrical wall, and haying a larger diameter than the first cylindrical wall, and
a first upper wall connecting a lower end of the first cylindrical wall and an upper end of the second cylindrical wall,
the second base member includes
a third cylindrical wall having a cylindrical shape coaxial with the first cylindrical wall, having a smaller diameter than the first cylindrical wall, and arranged in a space surrounded by the first cylindrical wall,
a fourth cylindrical wall having a cylindrical shape coaxial with the first cylindrical wall, having a larger diameter than the third cylindrical wall, having a smaller diameter than the second cylindrical wall, and arranged in a space surrounded by the second cylindrical wall, and
a second upper wall arranged below the first upper wall, and connecting a lower end of the third cylindrical wall and an upper end of the fourth cylindrical wall,
the shower plate includes a plurality of through holes, and is arranged at a lower end of the second cylindrical wall and a lower end of the fourth cylindrical wall, and
each of the heat transfer members is arranged between the first upper wall and the second upper wall and is in contact with a lower surface of the first upper wall and an upper surface of the second upper wall.
